(19) United States
(12) Patent Application Publication
(10) Pub. No.: US 2017/0094788 A1
(43) Pub. Date: Mar. 30, 2017

(54) PRINTED CIRCUIT BOARD

(71) Applicant: FANUC Corporation, Yamanashi (JP)

(72) Inventor: Nobuhisa SUGIMOTO, Yamanashi (JP)

(21) Appl. No.: 15/278,029

(22) Filed: Sep. 28, 2016

(30) Foreign Application Priority Data
Sep. 29, 2015 (JP) 2015-191605

(51) Int. Cl. H05K 1/11

(52) U.S. Cl. CPC H05K 1/111; H05K 2201/094; H05K 2201/09418

(57) ABSTRACT

An electronic part having a plurality of signal terminals aligned as a terminal line along at least one side of the main body of the package is to be mounted onto the printed circuit board according to the present invention, which is provided with pads aligned as a pad line corresponding to the above-described signal terminal line where the above-described pad line includes at least one first pad having a predetermined length and at least one second pad shorter than that of the first pad. The first pads and the second pads are arranged in such a manner that the distal end sides of the first and the second pads to be located at the end portions of the signal terminals upon mounted the above-described electronic part are aligned on a line, and none of the first pads are adjacent to each other.

### BACKGROUND OF THE INVENTION

1. Field of the Invention

The present invention relates to a printed circuit board on which electronic parts are to be mounted.

2. Description of the Related Art

Electronic parts such as QFPs (quad flat packages) and SOPs (small outline packages) are mounted onto a printed circuit board when a plurality of signal terminals extending from sides of the main bodies of the packages are soldered to pads that are provided on the printed circuit board so as to correspond to the above-described signal terminals.

FIG. 6 is a diagram showing an example of an electronic part having signal terminals aligned as a line. Each terminal is of a gull wing shape. An electronic part 10 has a main body 11 that is molded with a resin. A plurality of signal terminals 12 are drawn out from the four sides of the main body 11 in a rectangular shape. A plurality of signal terminals 12 that are drawn out from one side of the main body 11 form a signal terminal line 13. The respective signal terminals 12 are soldered to pads (not shown) provided on the printed circuit board (not shown) so as to correspond to the respective signal terminals 12 when the electronic part 10 is mounted onto the printed circuit board.

Some electronic parts such as QFPs and SOPs that have electrode terminals (signal terminals) on sides of the main body of the package are narrow pitch electronic parts where the pitch between electrode terminals is as narrow as 0.5 mm or 0.4 mm, which in some cases causes a problem that is called a bridge defect where adjacent terminals are short circuited through a solder at the time of soldering.

FIG. 7 is a diagram illustrating pads aligned as a line provided on a conventional printed circuit board. FIG. 8 is a diagram showing the state where a signal terminal is soldered to a pad. A plurality of pads 21 are provided on a printed circuit board 20 so as to respectively correspond to the signal terminals 12 provided on an electronic part 10 that is to be mounted onto the printed circuit board 20. A plurality of pads 21 form one pad line 22. The pads 21 those forming a pad line 22 have the same length L1.

In FIG. 7, two pairs of pad lines 22 are provided. The signal terminals 12 of the electronic part 10 (see FIG. 6) are respectively soldered to the pads 21 in the two pairs of pad lines 22. The distal end sides 21a of the pads 21 are on the side close to the end portions 12a of the signal terminals 12 that are soldered to the pads 21. The proximal end sides 21b of the pads 21 are on the side close to the base portions 12c of the signal terminals 12 that are on the opposite side of the signal terminals 12. The distal end sides 21a and the proximal end sides 21b of the pads 21 may be referred respectively to as the outside and the inside of the pads 21.

As shown in FIG. 8, a signal terminal 12 extending from the main body 11 of an electronic part 10 has a base portion 12c, a middle portion 12b and an end portion 12a from the side closer to the main body 11. Signal terminals 12 are formed in such a manner that the middle portion 12b is bent downward from the base portion 12c extending from the main body 11 in a horizontal direction, and the end portion 12a is bent so as to cancel the amount of the bending between the base portion 12c and the middle portion 12b, and thus, the end portion 12a runs in an almost horizontal direction (almost parallel to the surface of the main body 11 and almost parallel to the surface of a pad 21).

The end portion 12a of a signal terminal 12 is soldered to a pad 21. In a case where the amount of solder that is applied to a pad 21 is large, such a problem arises that a solder bridge is easily formed between adjacent pads 21 when adjacent molten solder pieces make contact with each other when the solder is molten.

When the end portion 12a of a signal terminal 12 is soldered to a pad 21, a back fillet 14 is formed between the signal terminal 12 and the pad 21 on the proximal end side 21b of the pad 21. Though a large back fillet 14 is effective in securing the joint strength, a large amount of solder that is supplied to form such a back fillet makes it easy to form a solder bridge.

Various types of measures against solder bridges have been proposed so far, and Japanese Unexamined Patent Publication 2007-258524 discloses one of these technologies. FIG. 9 is a diagram illustrating the printed circuit board that is disclosed in Japanese Unexamined Patent Publication 2007-258524. A plurality of lands 3 are formed on a printed circuit board 1 so as to be connected to terminals 7 that protrude from and are aligned along the end surfaces of a surface mount type semiconductor device 6. The lands 3 are provided in such a manner that the centers are shifted to the front and to the rear alternately in the direction in which the terminals 7 protrude from the semiconductor device 6, and thus, the centers stagger along the end surfaces of the semiconductor device 6. In addition, a solder printed region 4 onto which a solder is applied is formed in the lands 3 in order to provide a connection region to which a terminal 7 of the semiconductor device 6 is connected. At the same time, surplus regions 3a, 3b and 3c into which surplus molten solder may flow when the solder is molten are formed alternately along the end surfaces of the semiconductor device 6 in the front and in the rear of the connection regions in the direction in which the terminals 7 protrude from the semiconductor device 6.

The mode in FIG. 9 has such a problem that the part mounting region is large due to the surplus regions provided on the outer portions of the lands (pads). In addition, the form of some parts may make it difficult to secure surplus regions provided on the inner portions of the lands (pads), or there is a possibility that such surplus regions may induce another problem.

### SUMMARY OF THE INVENTION

In view of the above-described problems with the prior art, an object of the present invention is to provide a printed circuit board on which a plurality of pads are formed so as to be connected to signal terminals that protrude from and are aligned along the side surfaces of the main body of the package of a surface mount type electronic part, where adjacent pads can be prevented from being short circuited through contact between solder pieces when the electronic part is mounted onto the printed circuit board.

The printed circuit board according to the present invention is characterized by being provided with first pads and second pads in each pad line where the first pads are longer than the second pads, and none of the first pads are adjacent to each other.

In addition, an electronic part having a plurality of signal terminals aligned as terminal line along at least one side of the outer periphery of the main body of the package is to be mounted onto the printed circuit board according to the present invention, which is provided with pads aligned as a pad line corresponding to the above-described signal terminal line where the above-described pad line includes at least one first pad and at least one second pad shorter in its length than the first one, and which is characterized in that the first and the second pads are arranged in such a manner that the distal end side of the pads located at the end portions of the signal terminals when the above-described electronic part is mounted, and are aligned as a line, and none of the first pads are adjacent to each other.

The first pads and the second pads alternate in the above-described pad line provided on the above-described printed circuit board.

In addition, the pads at the two ends of the above-described pad line are first pads.

The present invention provides a printed circuit board on which a plurality of pads are formed so as to be connected to signal terminals that protrude from and are aligned along the end surfaces of the main body of the package of a surface mount type electronic part, where adjacent pads can be prevented from being short circuited due to contact between solder pieces when the electronic part is mounted onto the printed circuit board.

### BRIEF DESCRIPTION OF THE DRAWINGS

The above-described and other objects and features of the present invention will be clarified from the following descriptions of the embodiments in reference to the accompanying drawings, from among which:

FIG. 1 is a diagram showing a case where the first pads and the second pads define pad lines, and the number of pads in each pad line is an odd number;

FIG. 2A is a diagram showing a state where a signal terminal is soldered to a first pad;

FIG. 2B is a diagram showing a state where a signal terminal is soldered to a second pad;

FIG. 3 is a diagram showing a case where the first pads and the second pads define pad lines, and the number of pads in each pad line is an even number;

FIG. 4 is a diagram illustrating an embodiment where the number of pads in each pad line is an even number, and the pads at the two ends of each pad line are first pads;

FIG. 5 is a diagram illustrating a printed circuit board where the number of pads in each pad line is an even number, the first pads and the second pads define the pad lines, none of the first pads are adjacent to another first pad, and first pads are placed at the two ends of each pad line;

FIG. 6 is a diagram showing an example of an electronic part having lines of signal terminals in a gull wing shape;

FIG. 7 is a diagram illustrating pad lines provided on a conventional printed circuit board;

FIG. 8 is a diagram showing the state where a signal terminal is soldered to a pad; and

FIG. 9 is a diagram illustrating the printed circuit board disclosed in Japanese Unexamined Patent Publication 2007-258524.

### DETAILED DESCRIPTION OF THE PREFERRED EMBODIMENTS

In the following, the embodiments of the present invention are described with reference to the drawings. Here, the configurations that are the same as or similar to those in the prior art are described with reference to the same drawings.

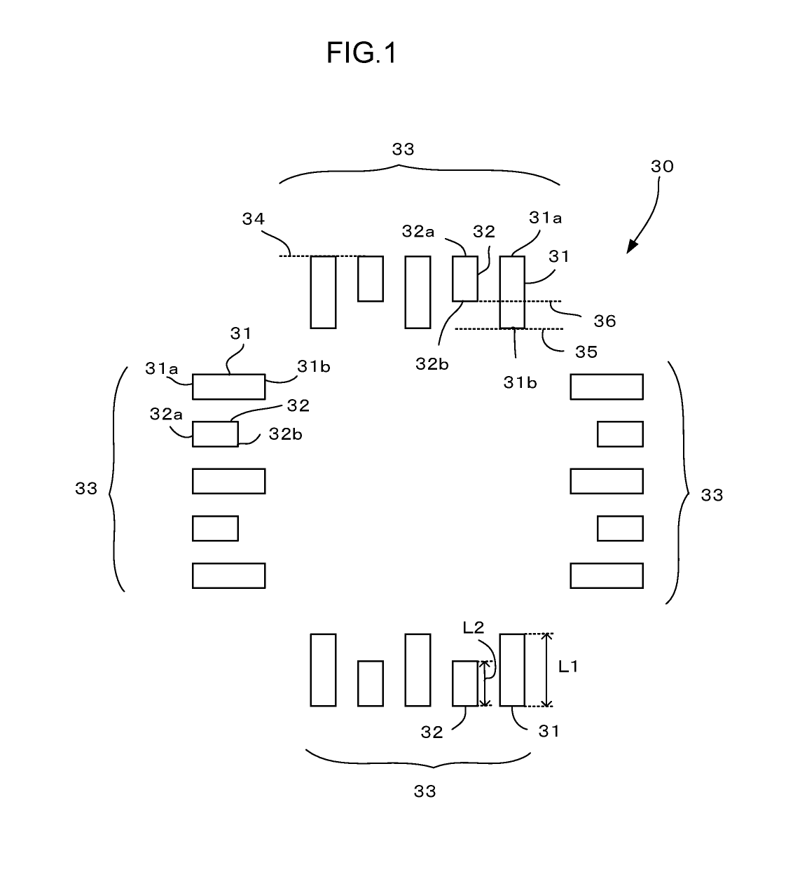

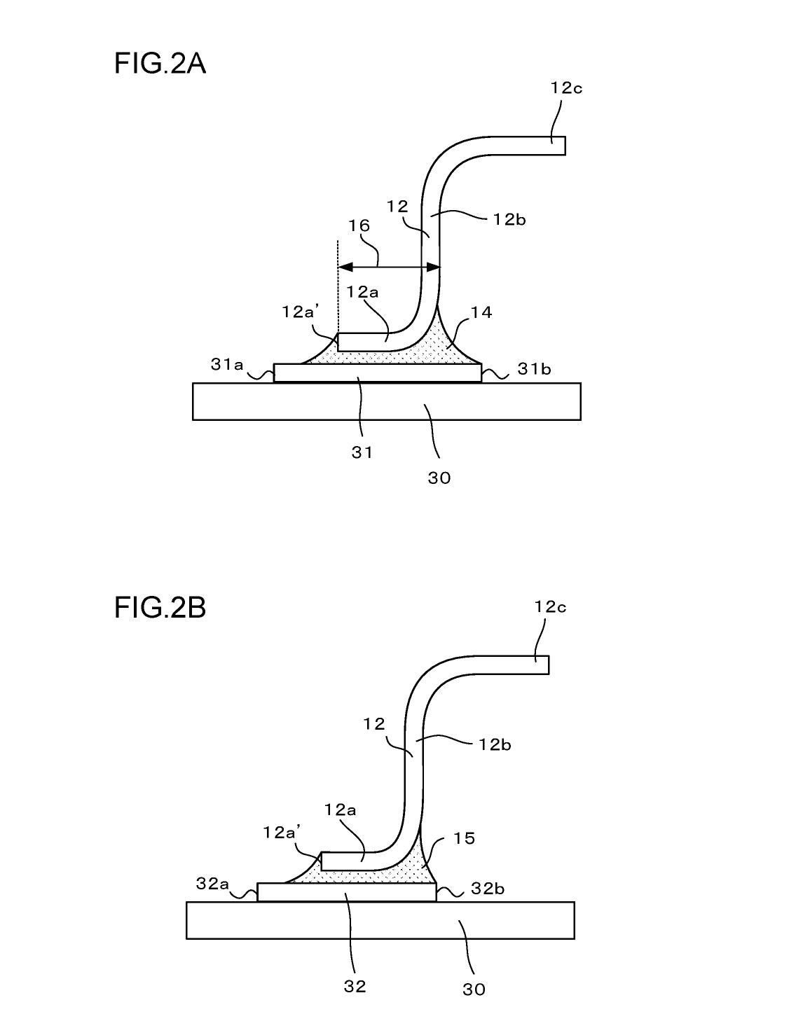

FIG. 1 is a diagram illustrating a printed circuit board where each pad line have the first pads and the second pads, and none of the first pads are adjacent to another first pad. FIG. 2A is a diagram showing a state where a signal terminal is soldered to a first pad. FIG. 2B is a diagram showing a state where a signal terminal is soldered to a second pad.

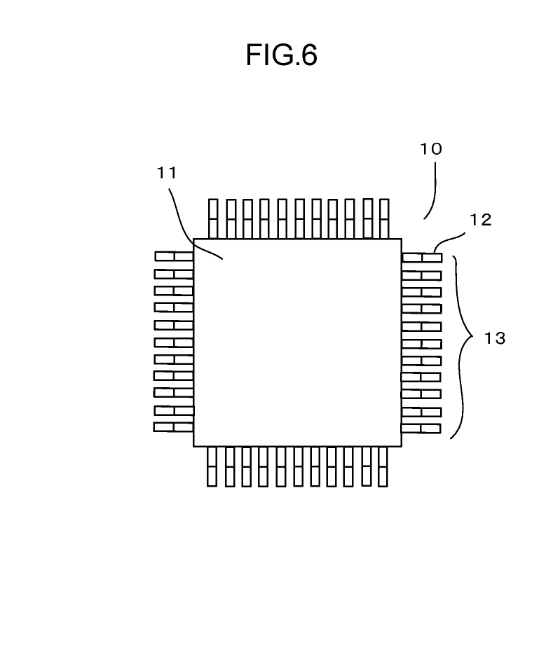

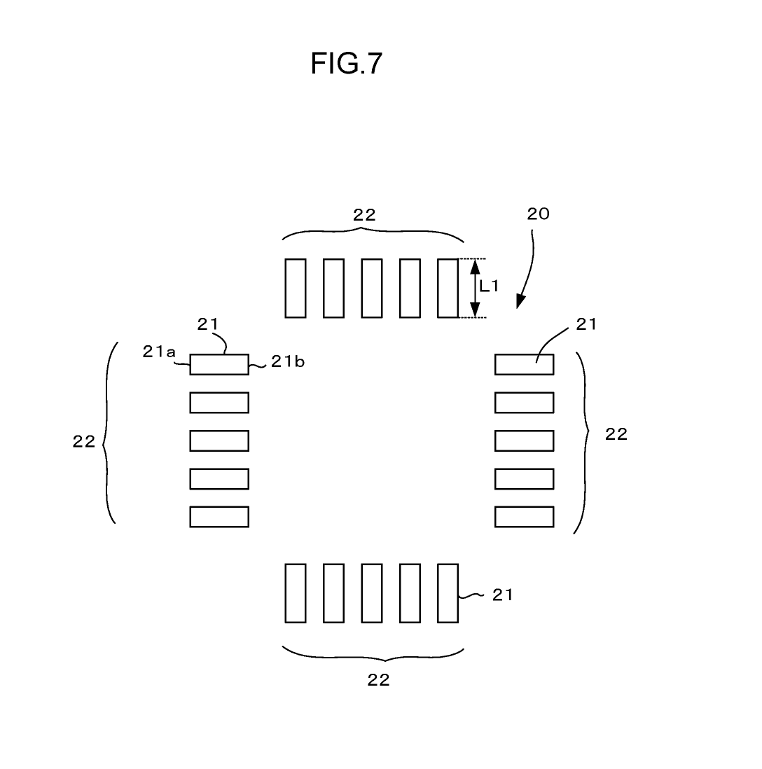

A creamy solder is applied to the pads provided on a printed circuit board 30. Each signal terminal 12 of the electronic part 10 having signal terminal lines 13 made of a plurality of signal terminals 12 on the outer periphery of the main body of the package is placed on the creamy solder on each pad, and the entirety of the printed circuit board 30 on which the electronic part 10 is mounted is heated so that the signal terminals 12 are soldered to the corresponding pads. An example of the mounted electronic part 10 is an electronic part having lines defined by signal terminals of a gull wing shape as shown in FIG. 6.

The printed circuit board 30 has pad lines 33 that correspond to signal terminal lines 13 extending from the sides of the main body of the package of the mounted electronic part 10. One pad line 33 includes at least one first pad 31 having a length L1 and at least one second pad 32 having a length L2 that is shorter than the length L1 of the first pad 31 (L1>L2). The first pads 31 are long pads, and the second pads 32 are short pads. The length L1 of the first pads 31 and the length L2 of the second pads 32 are longer than the length of the end portions 12a of the signal terminals 12 of the electronic part 10. In addition, the first pads 31 and the second pads 32 are longer than the length 16 of the end portions of the signal terminals 12 (see FIGS. 2A and 2B). In addition, the width of the pads 31 and 32 is restricted by the pitch between the terminals of the part to be mounted and the form of the terminals, and thus, the gaps between the pads are determined.

The first pads 31 and the second pads 32 forming a pad line 33 are arranged on a printed circuit board in such a manner that the distal end sides 31a of the first pads 31 and the distal end sides 32a of the second pads 32 are aligned on a line, and none of the first pads 31 are adjacent to each other. The distal end sides of the respective pads that form one pad line 33 (the end sides 31a of the first pads 31 and the end sides 32a of the second pads 32) are aligned along the dotted line 34. As for the rear end sides of the respective pads, the line along which the proximal end sides 31b of the first pads 31 are aligned (dotted line 35) and the line along which the proximal ends sides 32b of the second pads 32 are aligned (dotted line 36) are located in offset manner due to the difference in the length between the first pads 31 and the second pads 32. None of the first pads 31 are adjacent to each other in order to prevent adjacent pads from being short circuited.

Here, the relationship between the length of the first pads 31, the length of the second pads 32 and the length of the end portions 12a of the signal terminals 12 is not limited to that shown in FIGS. 2A and 2B. For example, the length of the second pads 32 may be so short that no back fillet 15 is formed as long as the end portion 12a of the signal terminal 12 and the second pad 32 make electrical connection without fail.

In addition, the first pads 31 in a pad line put importance on the joint strength, and thus, the proximal end side 31b extends towards the center of the mounted electronic part more than the proximal end side of the end portion 12a of the signal terminal 12 (right side of the right arrow symbol in FIG. 2A).

The distal end side 31a of the first pad 31 is the side close to the end side 12a′ of the end portion 12a of the signal terminal 12 that is soldered to the first pad 31, and the proximal end side 31b is the side close to the base portion 12c of the signal terminal 12 on the side opposite the end portion 12a. The distal end side 31a and the proximal end side 31b of the first pad 31 may also be referred to as the outside and the inside of the first pad 31, respectively. Likewise, the distal end side 32a and the proximal end side 32b of the second pad 32 may also be referred to as the outside and the inside of the second pad 32, respectively. In this case, it can be said that the second pads 32 that are shorter than the first pads 31 by the length of the inner side portion are arranged on a printed circuit board 30.

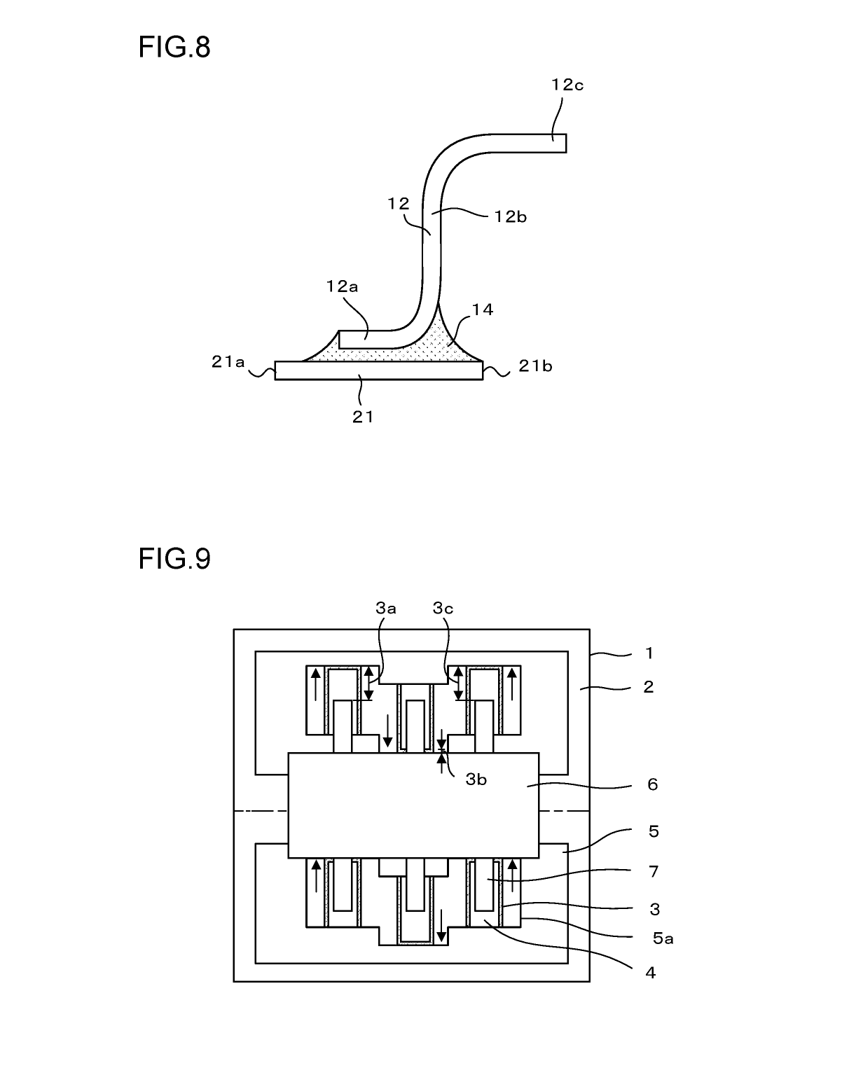

An electronic part 10 is mounted onto a printed circuit board 30. The respective signal terminals 12 in a signal terminal line 13 are soldered to the pads in the corresponding pad line 33 (first pads 31 and second pads 32). FIG. 2A shows a case where a signal terminal 12 is soldered to a first pad 31. This is the same state as in FIG. 8, where a back fillet 14 is formed. In contrast, a back fillet 15 is formed on a second pad 32 on the proximal end side 32b when a signal terminal 12 is soldered to the second pad 32. The thus-formed back fillet 15 is smaller than the back fillet 14 in the case in FIG. 2A.

Since the back fillet 15 is smaller than the back fillet 14 in size, the amount of solder that is supplied to the back fillet on the second pads 32 is smaller than that on the first pads 31. Here, the amount of solder supplied to the second pads 32 per unit area of the pad is not made smaller than that supplied to the first pads 31 in order to prevent the number of open defects from increasing.

Since the amount of solder supplied to the back fillet on the second pads 32 is lower, it becomes difficult for adjacent molten solder pieces to make contact with each other as compared to a case where first pads 31 are adjacent to each other. As a result, a solder bridge is prevented from being formed between a first pad 31 and a second pad 32.

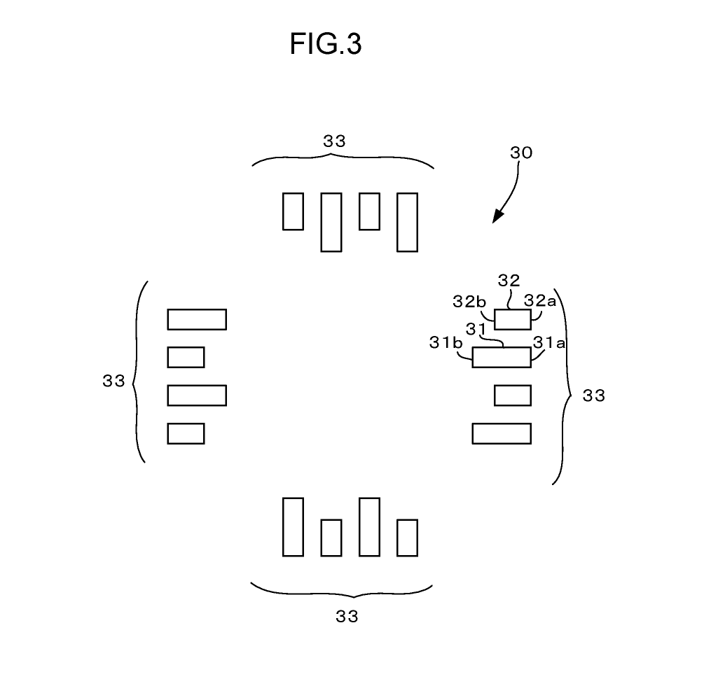

FIG. 1 shows a case where the number of pads in a pad line is an odd number, and FIG. 3 shows a case where the number of pads in a pad line is an even number. FIG. 3 is a diagram illustrating an embodiment where first pads and second pads are arranged alternately in a pad line. The embodiment is characterized in that first pads 31 and second pads 32 are disposed alternately in a pad line 33.

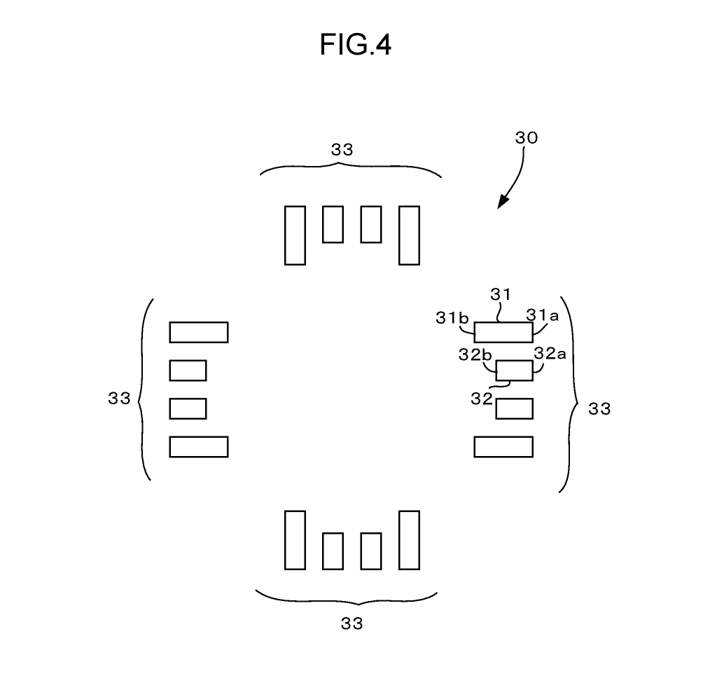

FIG. 4 is a diagram illustrating an embodiment where the number of pads in a pad line is an even number, and first pads are placed at the two ends of the pad line. The pads at the two ends of a pad line are susceptible to being damaged due to the temperature cycle, and therefore, first pads 31 having a higher degree of joining are selected for the pads at the two ends of the pad line 33 so that the soldering strength can be secured when an electronic part is mounted.

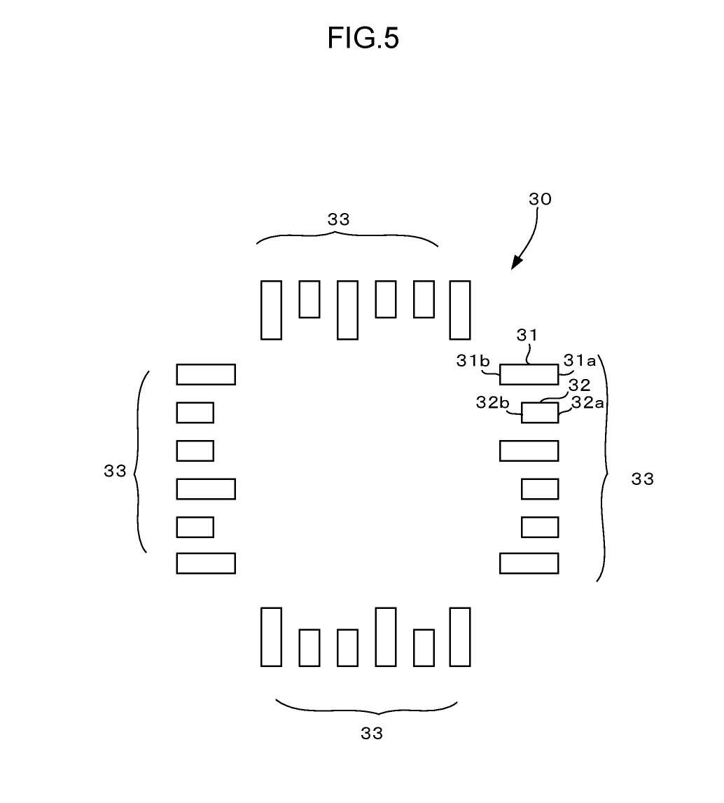

In FIG. 5, the pad lines 33 have first pads 31 and second pads 32 where none of the first pads 31 are adjacent to another first pad 31, and first pads 31 are selected as the pads at the two ends of a pad line 33 so that the soldering strength can be secured when an electronic part is mounted.

The above-described embodiment of the present invention provides a case where an electronic part having signal terminal lines along all of the four sides around the main body of the package is mounted on a printed circuit board. However, the invention is not limited to this embodiment, and another embodiment of the present invention provides a printed circuit board on which an electronic part having a signal terminal line along one side of the main body of the package is mounted. In addition, other embodiments of the present invention provide a printed circuit board on which an electronic part having signal terminal lines along two opposite sides or two adjacent sides of the main body of the package is mounted.

Likewise, still another embodiment provides a printed circuit board on which an electronic part having signal terminal lines along three sides of the main body of the package is mounted.

Though the embodiments of the present invention are described in the above, the present invention is not limited to these embodiments and can be implemented in other modes by applying appropriate modifications.

1. A print circuit board onto which an electronic part having a plurality of signal terminals aligned as a terminal line along at least one side of the package thereof is to be mounted comprising:
Pads aligned as a pad line corresponding to the terminal line,
The pad line includes at least one first pad and at least one second pad shorter in its length than the first one,
The first and the second pads are arranged in such manner that the distal end sides of the pads to be located at the end portions of the terminals upon mounted the electronic part are aligned on a line, and none of the first pads are adjacent with each other.

2. The printed circuit board according to claim 1, wherein the first pads and the second pads are alternately disposed in the pad line.

3. The printed circuit board according to claim 1, wherein the first pads are arranged at the two ends of the pad line.
